(19) United States
(12) Patent Application Publication
(10) Pub. No.: US 2015/0163931 A1
(43) Pub. Date: Jun. 11, 2015

(54) CRASH PREVENTING APPARATUS

(71) Applicants: Fu Tai Hua Industry (Shenzhen) Co., Ltd., Shenzhen (CN); HON HAI PRECISION INDUSTRY CO., LTD., New Taipei (TW)

(72) Inventor: JIN-LONG FU, Shenzhen (CN)

(21) Appl. No.: 14/525,426

(22) Filed: Oct. 28, 2014

(30) Foreign Application Priority Data
Dec. 5, 2013 (CN) 201310644952.2

(51) Int. Cl. H05K 5/02; F16B 2/10

(52) U.S. Cl. CPC H05K 5/0204; F16B 2/10

(57) ABSTRACT

A crash preventing apparatus includes a latching device and an actuator. The latching device includes a rotatable member, a first gripping member, and a second gripping member. The rotatable member includes a first arm and a second arm. The first gripping member and the second gripping member are respectively fixed to a first portion of the first arm and a first portion of the second arm. The actuator includes a shaft, a first line, a second line, and a line connector. A first end of the first line and a first end of the second line pass over the shaft in opposite directions, and are respectively connected to a second portion of the first arm and a second portion of the second arm. A second end of the first line and a second end of the second line are connected to the line connector.

### CROSS-REFERENCE TO RELATED APPLICATIONS

This application claims priority to Chinese Patent Application No. 201310644952.2 filed on Dec. 5, 2013, the contents of which are incorporated by reference herein.

### FIELD

The subject matter herein generally relates to crash preventing apparatus, and particularly, to a crash preventing apparatus capable of protecting an electronic device from a fall.

### BACKGROUND

An electronic device may be damaged in an event that the electronic device falls from a table when the electronic device is communication with a computer or charged via a connection wire.

### BRIEF DESCRIPTION OF THE DRAWINGS

Implementations of the present technology will now be described, by way of example only, with reference to the attached figures.

FIG. 1 is an isometric view showing an embodiment of a crash preventing apparatus holding an electronic device.

FIG. 2 is an isometric view showing an embodiment of the crash preventing apparatus of FIG. 1, but omitting a fixing device.

FIG. 3 is an exploded, isometric view showing the crash preventing apparatus of FIG. 2.

FIG. 4 is a side elevational view of the crash preventing apparatus of FIG. 2, showing a working principle of the crash preventing apparatus.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

A definition that applies throughout this disclosure will now be presented.

The term “comprising” means “including, but not necessarily limited to”; it specifically indicates open-ended inclusion or membership in a so-described combination, group, series and the like.

Embodiments of the present disclosure will be described in relation to the accompanying drawings.

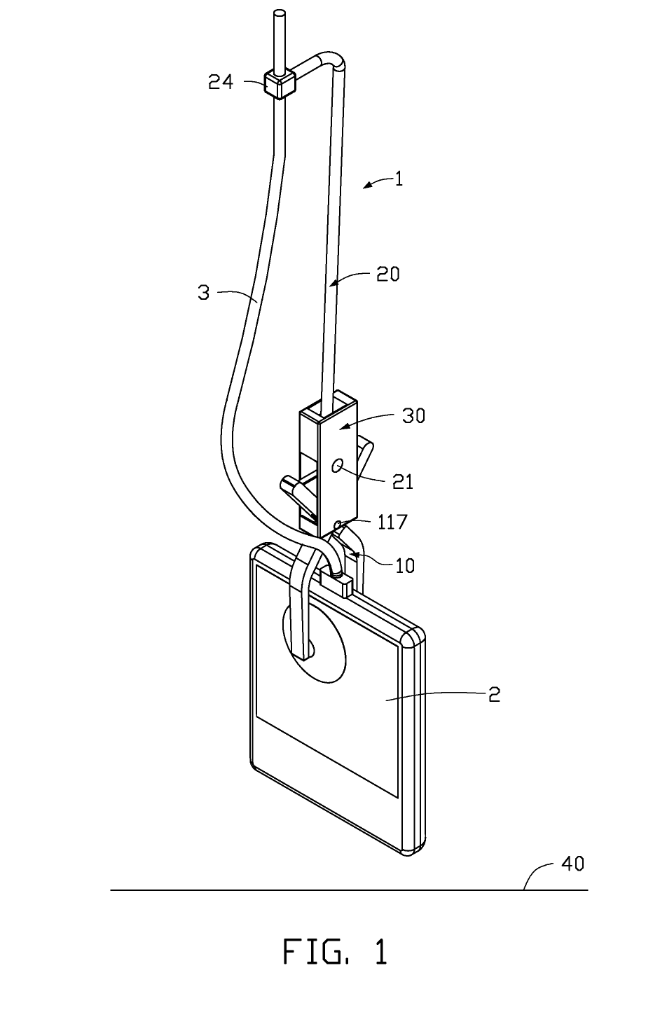

FIG. 1 illustrates an embodiment of a crash preventing apparatus 1. The crash preventing apparatus 1 can protect an electronic device 2. In the embodiment, the electronic device 2 may be in communication with a computer (not shown) or charged by a power adapter (not shown) or the computer (not shown) via an outside object 3. In the embodiment, the outside object 3 is a connection line. The crash preventing apparatus 1 can include a latching device 10 and an actuator 20. When the electronic device 2 is dropped toward a surface 4, the actuator 20 can move the latching device 10 to hold the electronic device 2, which protects the electronic device 2 from a fall.

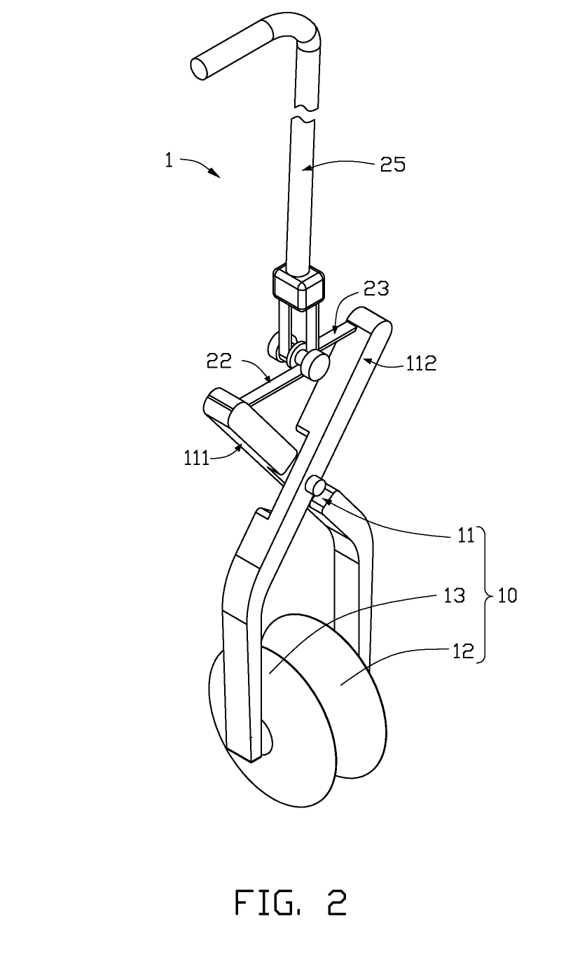

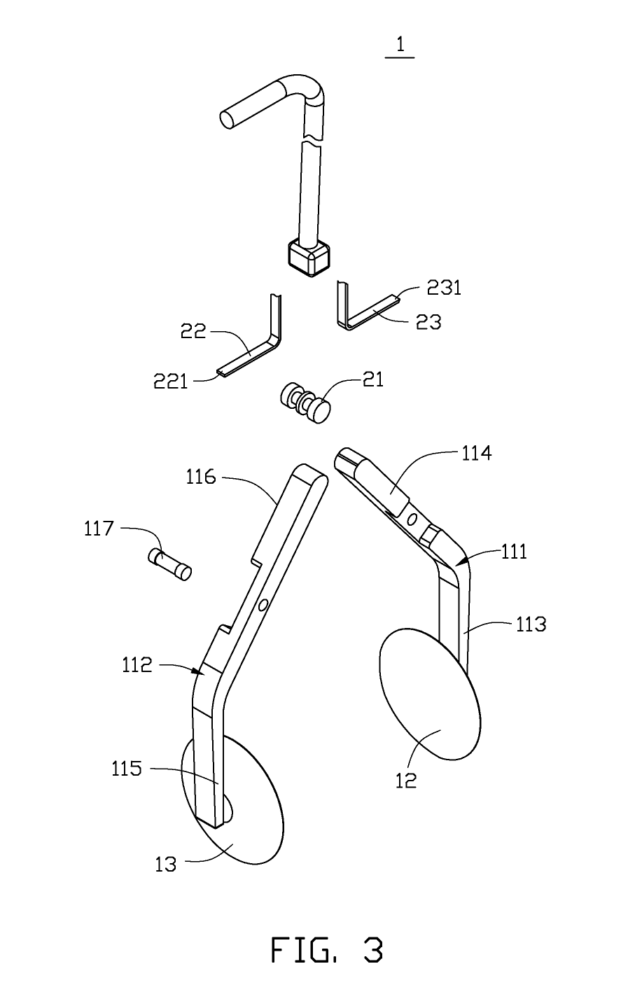

FIGS. 2-4 illustrate a detail structure of the crash preventing apparatus 1. The latching device 10 can include a rotatable member 11, a first gripping member 12, and a second gripping member 13. The rotatable member 11 can include a first arm 111 and a second arm 112. The first arm 111 and the second arm 112 can be pivoted connected to each other. In the embodiment, the first arm 111 includes a first portion 113 and a second portion 114, and the second arm 112 includes a first portion 115 and a second portion 116. The first gripping member 12 and the second gripping member 13 are opposite to each other. In the embodiment, the first gripping member 12 is fixed to the first portion 113 of the first arm 111, and the second gripping member 13 is fixed to a first portion 115 of the second arm 112. The first gripping member 12 and the second gripping member 13 can clamp opposite surfaces of the electronic device 2. In the embodiment, the first gripping member 12 and the second gripping member 13 are respective a cupule.

The actuator 20 can include a shaft 21, a first line 22, a second line 23, and a line connector 24. The first line 22 and the second line 23 pass around the shaft 21 in opposite directions. The first line 22 includes a first end 221 and a second end 222. The first end 221 of the first line 22 is connected to the second portion 114 of the first arm 111, and the second end 222 of the first line 22 is connected to the line connector 24. The second line 23 includes a first end 231 and a second end 232. The first end 231 of the second line 23 is connected to the second portion 116 of the second arm 112, and the second end 232 of the second line 23 is connected to the line connector 24. In the embodiment, a length of the first line 22 is the same as a length of the second line 23. The line connector 24 is connected to the outside object 3. In the embodiment, the position of the line connector 24 can be adjusted by a user. For example, the outside object 3 can include more than one point at different position. The line connector 24 can be adjusted to fix to one of the points of the outside object 3. Alternatively, the position of the line connector 24 is fixed. In the embodiment, a length of the outside object 3 is greater than the length of the first line 22, and obviously, the length of the outside object 3 is greater than the length of the second line 23.

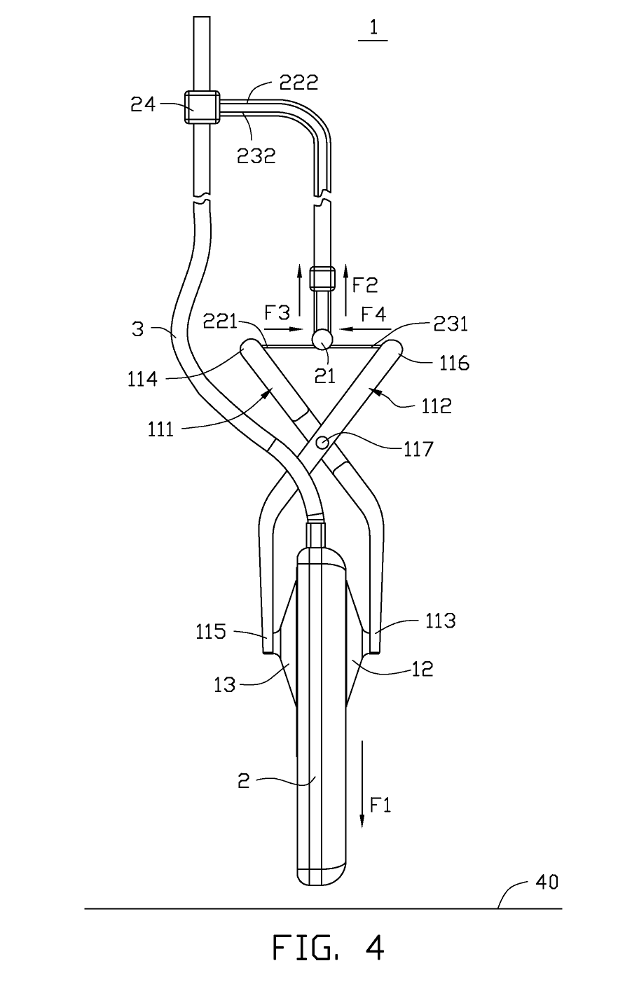

When working, the electronic device 2 is adsorbed by the first gripping member 12 and the second gripping member 13. When the electronic device 2 falls toward the surface 4, the electronic device 2 can bring the crash preventing apparatus 1 to fall due to gravity F1 of the electronic device 2, and a strain force F2 is accordingly generated to strain the first line 22 and the second line 23. The first line 22 and the second line 23 move upwards around the shaft 21 accordingly, a length of the first line 22 between the shaft 21 and the second portion 114 of the first arm 111 and a length of the second line 23 between the shaft 21 and the second portions 116 of the second arm 112 accordingly become shorter, and a pull force F3 and a pull force F4 are accordingly generated to close the second portion 114 of the first arm 111 and the second portion 116 of the second arm 112, namely, the first line 22 and the second line 23 move the second portion 114 of the first arm 111 toward the second portion 116 of the second arm 112. Thus, a relative distance between the first portion 113 of the first arm 111 and the first portion 115 of the second arm 112 become shorter, the first gripping member 12 accordingly moves toward the second gripping member 13, and the first gripping member 12 and the second gripping member 13 together to hold the electronic device 2 therebetween and above the surface 4 (see FIG. 4).

In the embodiment, the rotatable member 11 can further include a bolt 117. The first gripping member 12 can be fixed to the first portion 113 of the first arm 111 and the second gripping member 13 can be fixed to the first portion 115 of the second arm 112, the first gripping member 12 and the second gripping member 13 can be opposite to each other. The second portion 114 of the first arm 111 and the second portion 116 of the second arm 112 can be respectively fixed to the first portion 113 of the first arm 111 and the first portion 115 of the second arm 112, and can be respectively sloped with respect to the first portion 113 of the first arm 111 and the first portion 115 of the second arm 112. In another embodiment, the second portion 114 of the first arm 111 and the first portion 113 of the first arm 111 can be integrated together, and the second portion 116 of the second arm 112 and the first portion 115 of the second arm 112 can be integrated together. The second portion 114 of the first arm 111 and the second portion 116 of the second arm 112 can be pivoted connected to each other via the bolt 117 and be rotatable around the bolt 117 as a center.

In the embodiment, the crash preventing apparatus 1 can further include a fixing member 30 (see FIG. 1). The fixing member 30 can be fixed to the shaft 21 and the bolt 117 to prevent the shaft 21 from moving relative to the bolt 117.

In the embodiment, the actuator 20 can further include a protection case 25 pivoted to the first line 22 and the second line 23. The protection case 25 can prevent the first line 22 and the second line 23 from being damaged.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A crash preventing apparatus comprising:
a latching device comprising a rotatable member, a first gripping member, and a second gripping member; the rotatable member comprising a first arm and a second arm, the first arm and the second arm being pivoted connected to each other; and the first gripping member and the second gripping member being respectively fixed to a first portion of the first arm and a first portion of the second arm and being opposite to each other, and the first gripping member and the second gripping member being configured to adsorb opposite surfaces of an electronic device; and
an actuator comprising a shaft, a first line, a second line, and a line connector; a first end of the first line and a first end of the second line passing over the shaft in opposite directions, and being respectively connected to a second portion of the first arm and a second portion of the second arm; a second end of the first line and a second end of the second line being connected to the line connector;
wherein the first line and the second line is strained and move upwards around the shaft, a length of the first line between the shaft and the second portion of the first arm and a length of the second line between the shaft and the second portion of the second arm become shorter to close a second portion of the first arm and a second portion of the second arm, a relative distance between the first portion of the first arm and the first portion of the second arm become shorter, the first gripping member and the second gripping member together to clamp the electronic device therebetween.

2. The crash preventing apparatus as described in claim 1, wherein a length of the first line is the same as a length of the second line.

3. The crash preventing apparatus as described in claim 1, wherein the rotatable member further comprises a bolt; the first gripping member is fixed to the first portion of the first arm and the second gripping member is fixed to the first portion of second arm; the second portion of the first arm and the second portion of the second arm are respectively fixed to the first portion of the first arm and the first portion of the second arm, and are respectively sloped with respect to the first portion of the first arm and the first portion of the second arm; the second portion of the first arm and the second portion of second arm are pivoted connected to each other via the bolt and are rotatable around the bolt as a center.

4. The crash preventing apparatus as described in claim 3, further comprising a fixing member, wherein the fixing member is fixed to the shaft and the bolt to prevent the shaft from moving relative to the bolt.

5. The crash preventing apparatus as described in claim 1, wherein the protection line further comprises a protection case pivoted to the first line and the second line, and the protection case prevents the first line and the second line from being damaged.

6. A crash preventing apparatus for electronic devices comprising:
a first arm, the first arm having a first portion and a second portion;
a second arm, the second arm having a first portion and a second portion and pivotably attached to the first arm;
a first gripping member attached to the first portion of the first arm;
a second gripping member attached to the first portion of the second arm;
an actuator connected to the second portion of the first arm and the second portion of the second arm, the actuator having:
a first line having a first end and a second end;
a second line having a first end and a second end;
a shaft;
a line connector;
wherein, the first line passes around the shaft with the first end of the first line being connected to the second portion of the first arm and the second end of the first line being connected to the line connector;
wherein, the second line passes around the shaft with the first end of the second line being connected to the second portion of the second arm and the second end of the second line being connected to the line connector;
wherein, when the line connector is moved from the shaft, the first line and the second line move the second portion of the first arm toward the second portion of the second arm such that the first gripping member is moved toward the second gripping member;
wherein, the line connector is connectable an outside object and electronic device is positionable between the first gripping member and the second gripping member above a surface so that upon a fall toward the surface, the line connector moves the gripping members together to hold the electronic device therebetween and the line connector is positioned to prevent the electronic device from contacting the surface.

7. The crash preventing apparatus as described in claim 6, wherein a length of the first line is the same as a length of the second line.

8. The crash preventing apparatus as described in claim 6, wherein the rotatable member further comprises a bolt; the first gripping member is fixed to the first portion of the first arm and the second gripping member is fixed to the first portion of second arm; the second portion of the first arm and the second portion of the second arm are respectively fixed to the first portion of the first arm and the first portion of the second arm, and are respectively sloped with respect to the first portion of the first arm and the first portion of the first arm; the second portion of the first arm and the second portion of second arm are pivoted connected to each other via the bolt and are rotatable around the bolt as a center.

9. The crash preventing apparatus as described in claim 8, further comprising a fixing member, wherein the fixing member is fixed to the shaft and the bolt to prevent the shaft from moving relative to the bolt.

10. The crash preventing apparatus as described in claim 6, wherein the protection line further comprises a protection case pivoted to the first line and the second line, and the protection case prevents the first line and the second line from being damaged.
